(19) United States
(12) Patent Application Publication
(10) Pub. No.: US 2002/0008963 A1
(43) Pub. Date: Jan. 24, 2002

(54) Inter-circuit encapsulated packaging

(76) Inventors: Joseph T. DiBene, II, Oceanside, CA (US); David H. Hartke, Durango, CO (US)

Correspondence Address: GATES & COOPER LLP, Howard Hughes Center, Suite 1050, 6701 Center Drive West, Los Angeles, CA, 90045, US

(21) Appl. No.: 09/818,173

(22) Filed: Mar. 26, 2001

Related U.S. Application Data
(63) Continuation-in-part of application No. 09/353,428, filed on Jul. 15, 1999, now Pat. No. 6,304,450.
(63) Continuation-in-part of application No. 09/432,878, filed on Nov. 2, 1999.
(63) Continuation-in-part of application No. 09/727,016, filed on Nov. 28, 2000.
(63) Continuation-in-part of application No. 09/785,892, filed on Feb. 16, 2001.
(63) Continuation-in-part of application No. 09/798,541, filed on Mar. 2, 2001.
(63) Continuation-in-part of application No. 09/801,437, filed on Mar. 8, 2001.
(63) Continuation-in-part of application No. 09/802,329, filed on Mar. 8, 2001.
(60) Provisional application No. 60/196,059, filed on Apr. 10, 2000.
(60) Provisional application No. 60/219,813, filed on Jul. 21, 2000.
(60) Provisional application No. 60/232,971, filed on Sep. 14, 2000.
(60) Provisional application No. 60/251,222, filed on Dec. 4, 2000.
(60) Provisional application No. 60/251,223, filed on Dec. 4, 2000.
(60) Provisional application No. 60/251,184, filed on Dec. 4, 2000.

(51) Int. Cl. H05K 7/20

(52) U.S. Cl. 361/720

(57) ABSTRACT

A modular circuit board assembly is disclosed. The modular circuit board assembly comprises a substrate, a circuit board, and a component, disposed between the circuit board and the substrate, the component physically and electrically coupled to the substrate. In one embodiment, the circuit board also comprises an aperture allowing for the transmission of thermal energy from the component to a heat sink. In still another embodiment of the invention, the heat sink includes a mesa having surface features cooperatively interacting with surface features on the component or members mounted on the component to provide for location and/or retention.

### CROSS-REFERENCE TO RELATED APPLICATIONS

This application claims benefit of the following U.S. Provisional Patent Applications, each of which are incorporated by reference herein:

Application Serial No. 60/196,059, entitled “EMI FRAME WITH POWER FEED-THROUGHS AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH CURRENT MICROPROCESSOR POWER DELIVERY SYSTEMS,” by Joseph T. DiBene II, filed Jul. 21, 2000;

Application Serial No. 60/232,971, entitled “INTEGRATED POWER DISTRIBUTION AND SEMICONDUCTOR PACKAGE,” by Joseph T. DiBene II and James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO-I-PAK FOR POWER DELIVERY TO MICROELECTRONICS,” by Joseph T. DiBene II and Carl E. Hoge, filed Dec. 4, 2000; and

Application Serial No. 60/251,184, entitled “MICROPROCESSOR INTEGRATED PACKAGING,” by Joseph T. DiBene II, filed Dec. 4, 2000.

This patent application is also continuation-in-part of the following co-pending and commonly assigned patent applications, each of which applications are hereby incorporated by reference herein:

application Ser. No. 09/353,428, entitled “INTER-CIRCUIT ENCAPSULATED PACKAGING,” by Joseph T. DiBene II and David H. Hartke, filed Jul. 15, 1999;

application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999;

application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001; and

application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001;

application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001; and

application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001.

### BACKGROUND OF THE INVENTION

1. Field of the Invention

This invention relates in general to a methodology to improve thermal and mechanical issues created by increased interconnect density, increased power levels by electronic circuits and increased levels of integrated electronic packaging. The present invention addresses these issues by encapsulating the circuitry within a circuit board structure which improves thermal, mechanical and integrated circuit device management over existing technologies known in the art today.

2. Description of Related Art

As circuitry in electronics becomes more and more complex, packaging of the circuitry has become more difficult. The common method for packaging integrated circuits and other electronic components is to mount them on Printed Circuit Boards (PCBs).

Recently, the application of new organic laminates in the construction of Multi-Chip-Modules (MCMs) has brought about significant improvements in the packaging cost and density of electronic circuits. Throughout this patent reference will be made to PCBs which shall be meant to include technologies associated with MCMs as well.

Computer chip clocking speeds have also increased. This increase in speed has made it difficult to couple chips together in such a way that the chip speeds are completely useable. Further, heat generated by integrated circuits has increased because of the increased number of signals travelling through the integrated circuits. In addition, as die size increases interconnect delays on the die are beginning to limit the circuit speeds within the die. Typically, the limitations of a system are contributed to, in part, by the packaging of the system itself. These effects are forcing greater attention to methods of efficiently coupling high-speed circuits.

Packaging the integrated circuits onto PCBs has become increasingly more difficult because of the signal density within integrated circuits and the requirements of heat dissipation. Typical interconnections on a PCB are made using traces that are etched or pattern plated onto a layer of the PCB. To create shorter interconnections, Surface Mount Technology (SMT) chips, Very Large Scale Integration (VLSI) circuits, flip chip bonding, Application Specific Integrated Circuits (ASICs), Ball Grid Arrays (BGAs), and the like, have been used to shorten the transit time and interconnection lengths between chips on a PCB. However, this technology has also not completely overcome the needs for higher signal speeds both intra-PCB and inter-PCB, because of thermal considerations, EMI concerns, and other packaging problems.

In any given system, PCB area (also known as PCB “real estate”) is at a premium. With smaller packaging envelopes becoming the norm in electronics, e.g., laptop computers, spacecraft, cellular telephones, etc., large PCBs are not available for use to mount SMT chips, BGAs, flip chips or other devices. Newer methods are emerging to decrease the size of PCBs such as Build-Up-Multilayer technology, improved organic laminate materials with reduced thicknesses and dielectric constants and laser beam photo imaging. These technologies produce greater pressure to maintain the functionality of the PCB assembly in thermal, EMI and power application to the semiconductor devices. It can be seen, then, that there is a need in the art for a method for decreasing the size of PCBs while maintaining the functionality of PCBs. Further, there is a need for reducing the size of PCBs while using present-day manufacturing techniques to maintain low cost packaging. There is further a need to provide for a compact package of one or more PCBs that provides for integrated thermal and EMI management, while providing high-current/low-voltage power signals to chips mounted on the PCBs.

Designers have attempted to address such needs with designs such as that which is illustrated in U.S. Pat. No. 5,734,555, issued to McMahon. This design uses a collocated second circuit board that may include voltage regulation or power conversion capability. For cooling purposes, both the first PCB (to which the IC is mounted) and the second PCB include an aperture. A heat plug is inserted through the apertures to make thermal connectivity with the component and to provide a path for heat to dissipate from the component away from the package. Unfortunately, this package has several disadvantages and only partially addresses the problem of integrated EMI, thermal, and power management. First, the package requires an aperture to be located in both the first PCB and the second PCB. This reduces the real estate in the second circuit board available for signal routing and increases fabrication costs. Second, the package does not allow the entire surface of the component to be thermally coupled to the heat plug (since the component is larger than the aperture in the first circuit board). Third, the package routes power from the motherboard, through pins and traces in the first circuit board to the second circuit board for power conditioning, then back to the first circuit board and to the component. This circuitous route induces substantial impedance and can also contribute to EMI generation. Finally the McMahon reference discloses a package that uses pins which must be soldered or otherwise permanently connected to the holes in the circuit boards. Hence, the assembly is non-modular, and cannot be easily disassembled.

### SUMMARY OF THE INVENTION

To overcome the limitations in the prior art described above, and to overcome other limitations that will become apparent upon reading and understanding the present specification, the present invention discloses a modular circuit board assembly having a substrate, a circuit board, and a heat dissipating component that is disposed between the circuit board and the substrate and is physically and electrically coupled to the substrate. In one embodiment, the modular circuit board assembly includes a heat sink or other heat dissipation device having a mesa extending through an aperture in a VRM circuit board disposed between the heat sink and the component.

An object of the present invention is to provide more efficient usage of printed circuit board real estate. Another object of the present invention is to increase the density of electronics on printed circuit boards. Another object of the present invention is to provide heat transfer from devices on printed circuit boards.

These and various other advantages and features of novelty that characterize the invention are pointed out with particularity in the claims annexed hereto and form a part hereof. However, for a better understanding of the invention, its advantages, and the objects obtained by its use, reference should be made to the drawings which form a further part hereof, and to the accompanying detailed description, in which there is illustrated and described specific examples of a method, apparatus, and article of manufacture in accordance with the invention.

The foregoing design has particular advantages over prior art designs. For example, by placing the component on the same side of the substrate as the heat dissipation device, the substrate itself does not require an aperture and a heat slug to efficiently transfer thermal energy away from the component. This simplifies the design of the conductive paths in the substrate layers, and if desired, permits the substrate to include a greater number of circuit paths. It also reduces substrate fabrication costs. Further, this design provides a greater physical and thermal contact area between the heat dissipation device and the component, reducing the thermal impedance of the energy path from the component to the heat dissipation device. This design also permits the use of heat sinks with mesas to further reduce thermal impedance as well as the use of special location and/or retention features to assure structural integrity and ease of assembly.

### BRIEF DESCRIPTION OF THE DRAWINGS

Referring now to the drawings in which like reference numbers represent corresponding parts throughout:

FIGS. 1A-1D illustrate the construction of a printed circuit board assembly using the present invention;

FIGS. 2A-2C illustrates the construction of a printed circuit board assembly using the present invention for multiple heat generating integrated circuit devices;

FIG. 3 illustrates a spacer which is used in conjunction with the present invention;

FIGS. 4A-4C illustrate the construction of a printed circuit board using the present invention wherein the thermal heat sink is located outboard the active circuit area;

FIGS. 5A and 5B illustrate the thermal considerations of a printed circuit board embodying the present invention;

FIG. 6 illustrates a flow chart describing the steps used in practicing the present invention;

FIG. 7 is a diagram illustrating an embodiment of the present invention wherein the second PCB includes an aperture;

FIGS. 8A and 8B are diagrams illustrating an embodiment of the present invention wherein the second PCB includes an aperture and the heat sink includes a mesa;

FIGS. 8C-8F are diagrams illustrating an embodiment of the present invention wherein the heat sink or the component include surface features for location and/or retention;

FIG. 9 is a diagram illustrating an embodiment of the present invention wherein the second PCB is disposed adjacent the component; and

FIG. 10 is a diagram illustrating exemplary method steps used to practice one embodiment of the present invention.

### DETAILED DESCRIPTION OF THE PREFERRED EMBODIMENT

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses an encapsulated circuit assembly and a method for making such an assembly. The assembly comprises a first printed circuit board, a second printed circuit board, and heat transfer devices. The second printed circuit board comprises a heatsink or secondary heat transfer mechanism such as heat pipes and heat transfer devices imbedded within the second printed circuit board which thermally couples devices mounted on the first printed circuit board and the thermal heat sink of the second printed circuit board.

The present invention provides a method and apparatus for mounting integrated circuit devices onto PCBs that removes the heat from those devices that generate large amounts of heat. The present invention allows for air cooling, heat pipe cooling, or other methods of cooling devices, as well as a compact packaging design to allow for heat generating devices to be packaged into small volumes. Furthermore, the present invention can be expanded to provide beneficial aspects to the art of power distribution, containment of electromagnetic interference and electronic signal interconnect.

Encapsulated Circuit Assembly

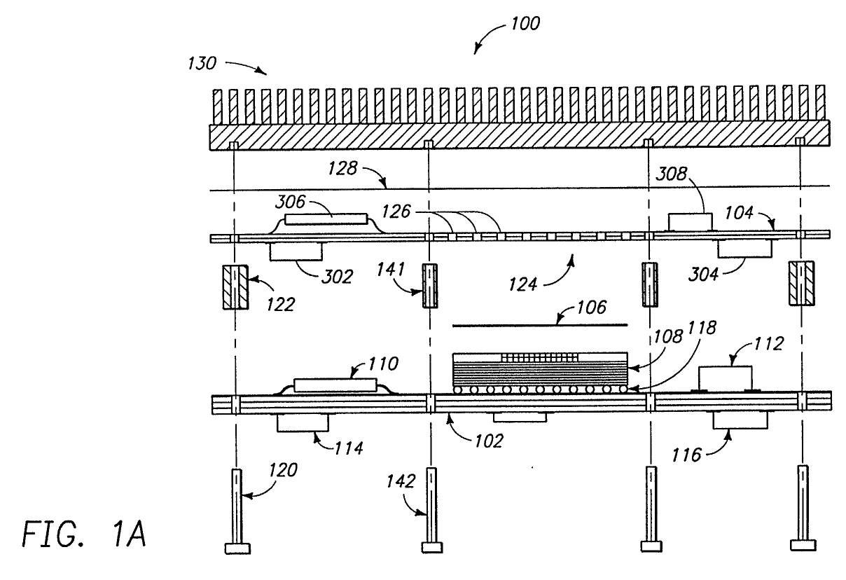

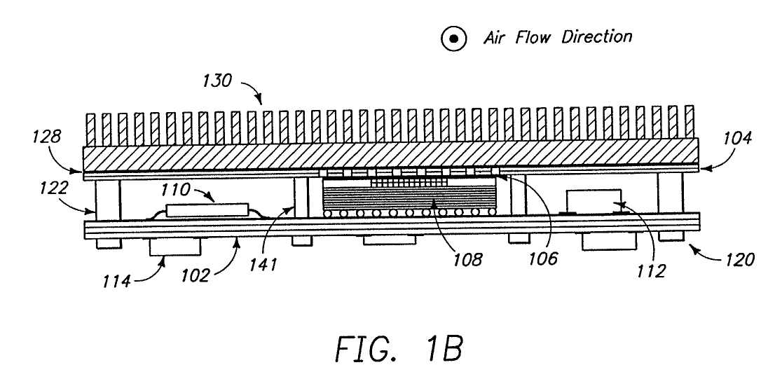

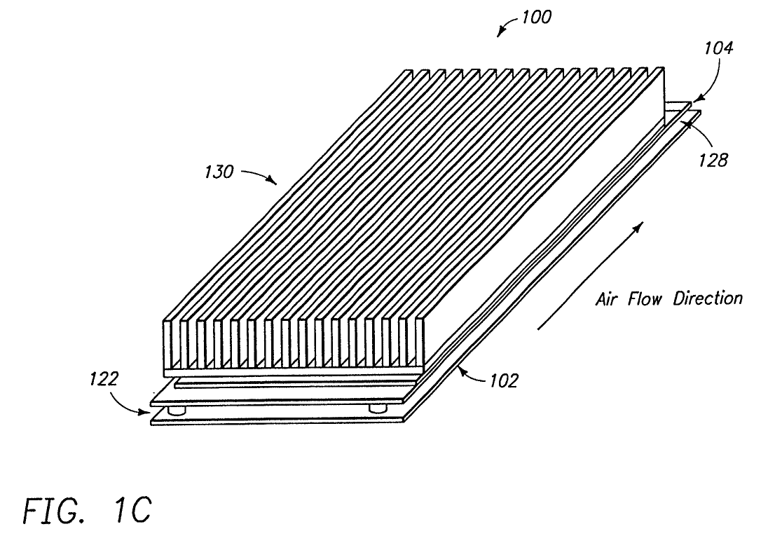

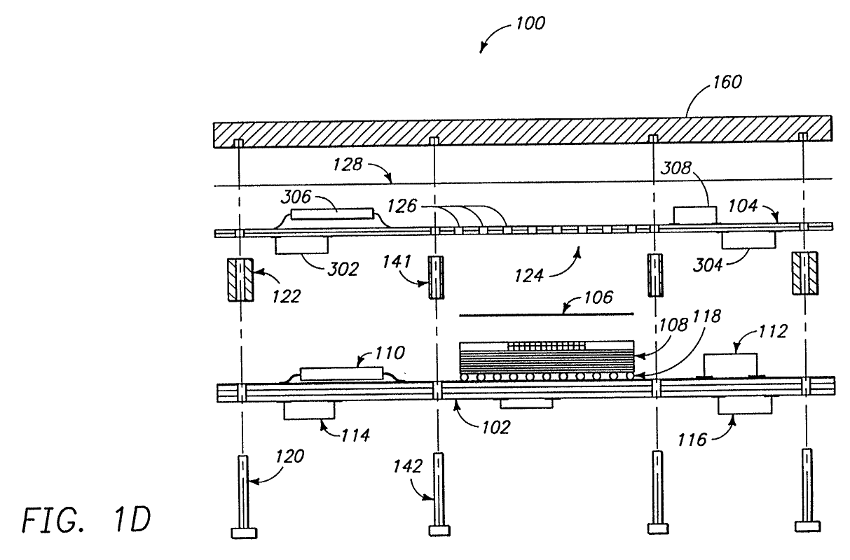

FIGS. 1A-1D illustrate the construction of an encapsulated circuit assembly using the present invention. FIG. 1A illustrates an exploded view of assembly 100. Assembly 100 comprises first printed circuit board (PCB) 102, second PCB 104, and heat transfer device 106. First PCB 102 can be a single layer PCB or multi-layer PCB, where the multi-layer PCB is comprised of alternating layers of conducting and non-conducting materials to allow electrical signals to be routed from device to device on the first PCB 102. Devices 108-116 are shown mounted on first PCB 102. Devices 114 and 116 are shown as being mounted on the opposite side of first PCB 102 as devices 108-112. This illustrates that first PCB 102 can have devices 108-116 mounted on both sides.

Device 108 is coupled to first PCB 102 via a Ball Grid Array (BGA) 118. BGA 118 provides electrical contacts between device 108 and first PCB 102. Other methods of electrical coupling between device 108 and first PCB 102 are possible, e.g., wire bonding, solder connections, etc. Further, there can also be thermal coupling between device 108 and PCB 102 if desired.

Heat transfer device 106 couples device 108 to second PCB 104. Heat transfer device 106 is typically a thermally conductive material, e.g., thermal grease, thermal epoxy, or a commercially produced material such as THERMA-GAP™. Heat transfer device 106 provides a thermal interface between device 108 and the second PCB 104. Heat transfer device 106 is typically a mechanically compliant material to allow for minimal applied pressure to the device 108 such that device 108 is not subjected to additional stress through use of heat transfer device 108.

Spacers 141 and fasteners 142 provide for a precision alignment between boards 102 and 104 and the device 108 such that a controlled gap exists in which heat transfer device 106 can properly be accommodated without deleterious air gaps nor excessive pressure applied to device 108. Additionally, the location of the spacers 141 adjacent to the device 108 reduce variations in spacing caused by bow and warpage of board 102 and, to some extent, board 104.

Devices 110-116 that are thermally active but do not require heat transfer device 106 to cool the devices 110-116 and are cooled by conduction through first PCB 102, or through convection should air flow be available across first PCB 102. Otherwise, additional devices 110-116 can be coupled to second PCB 104 through additional heat transfer devices 106. The present invention is not limited to a single device 108 that is cooled through the use of heat transfer device 106. Any number of devices 108-116 can be cooled through the use of single or multiple heat transfer devices 106.

Second PCB 104 is mechanically coupled to first PCB 102 through the use of fasteners 120 and standoffs 122. Fasteners 120 are typically screws, but can be other types of fasteners such as rivets, hollow feedthroughs, connectors, or other fasteners. Standoffs 122 are typically unthreaded inserts with a height equal to the height of spacer 141. The fasteners 120 and standoffs 122 are located at mechanically and/or electrically desirable locations on first PCB 102. These locations are typically at the periphery of first PCB 102, but can be anywhere on first PCB 102.

Second PCB 104 has areas 124 that are designed to facilitate the transfer of heat from device 108, through heat transfer device 106, to a heat sink. Areas 124 comprise plated through holes (PTHs) 126, consisting of holes in board 104 with interior walls of plated copper or other high thermally conductive material. In addition, the region within the hole may be filled with metal, liquid filled areas, or other thermal transfer devices or mechanisms to enhance thermal conduction between the material 106 and the heatsink 130. Areas 124 can be designed to be the same size, a larger size, or a smaller size than the device 108, depending on the heat dissipation requirements for device 108 and the size of second PCB 104. An additional benefit of PTHs 126 is to provide a means of reducing air pockets in material 106 and to provide a volume where excesses of material 106 may flow in the case of a reduced gap between device 108 and board 104. Still another benefit of PTHs 126 can be to adjust the thermal conductivity of the paths of multiple devices 108 on a single first PCB 102 to the common “isothermal” heatsink 130 such that if the two devices 108 have differing heat flow then the conductivity in each thermal path can be adjusted such that the junction temperature of each device 108 will be the same. This can be beneficial in improving timing margins of digital devices.

A thermal interface such as a plate 128 is coupled to second PCB 104 to equalize and transfer heat from device 108, through heat transfer device 106 and second PCB 104 area 124 to heat sink 130. Although shown as a finned heat sink, heatsink 130 can be any device, e.g., a heat pipe, or a layer on second PCB 104 that acts as an isothermal conduction layer to properly remove the heat generated by device 108. Thermal interface 128 can be electrically conductive, or non-electrically conductive, depending on the design for second PCB 104. For example, if devices 302-308 need to be mounted on second PCB 104, thermal interface 128 should be electrically non-conductive so as not to interfere with signals travelling between devices 108-116 that are mounted on second PCB 104. Thermal interface 128 can be thermal epoxy or any other material which thermally and mechanically bonds second PCB 104 to heatsink 130.

FIG. 1B illustrates the assembly 100 as a completed assembly. The thermal coupling of device 108, heat transfer device 106, second PCB 104 in conjunction with PTHs 126, thermal interface 128, and heatsink 130 provide a thermal path for heat generated by device 108 to be dissipated by heatsink 130. Further, airflow can be provided to further cool device 108 and devices 110-116. Although shown as covering the entire area of second PCB 104, heatsink 130 can be larger or smaller than the area of second PCB 104. Heatsink 130 also acts as a mechanical stabilizer for assembly 100, to provide additional mechanical stability for assemblies 100 that will experience more severe mechanical environments, e.g., vibration.

FIG. 1C illustrates assembly 100 in an isometric view. Heatsink 130 is shown as smaller than second PCB 104 and thermal interface 128 to illustrate the flexibility of the design of the present invention. Airflow can again be provided to increase the heat dissipation capabilities of assembly 100.

FIG. 1D illustrates an embodiment of the assembly 100 comprising a heat pipe 160.

Multiple Device Encapsulated Circuit Assembly

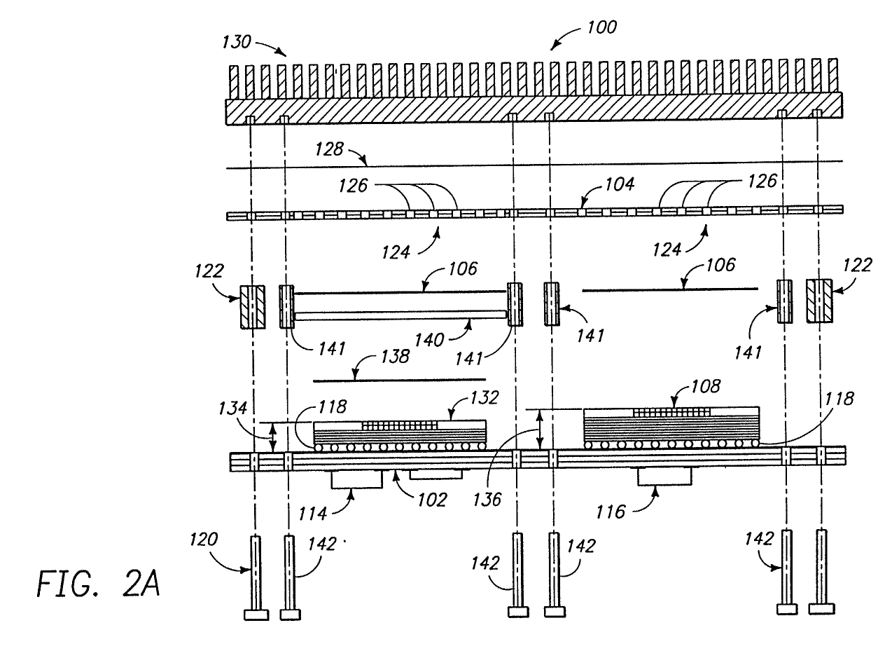

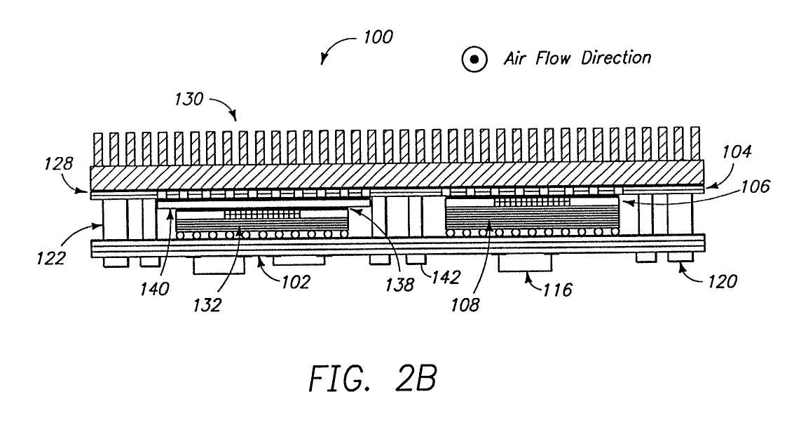

FIGS. 2A-2B illustrate the construction of an encapsulated circuit assembly using the present invention for multiple heat generating integrated circuit devices. FIG. 2A illustrates an exploded view of assembly 100. Assembly 100 comprises first printed circuit board (PCB) 102, second PCB 104, and heat transfer device 106. First PCB 102 can be a single layer PCB or multi-layer PCB, where the multi-layer PCB is comprised of alternating layers of conducting and non-conducting materials to allow electrical signals to be routed from device to device on the first PCB 102. Devices 108, 114-116, and 132 are shown mounted on first PCB 102. Devices 114 and 116 are shown as being mounted on the opposite side of first PCB 102 as devices 108 and 132. This illustrates that first PCB 102 can have devices 108, 114-116, and 132 mounted on both sides.

Devices 108 and 132 are coupled to first PCB 102 via a Ball Grid Array (BGA) 118. BGA 118 provides electrical contacts between devices 108 and 132 and first PCB 102. Other methods of electrical coupling between devices 108 and 132 and first PCB 102 are possible, e.g., Tape Automated Bonding (TAB), SMT, flip chip, etc. Further, there can also be thermal coupling between devices 108 and 132 and PCB 102 if desired.

Heat transfer device 106 couples device 108 to second PCB 104. Heat transfer device 106 is typically a thermally conductive material, e.g., thermal grease, thermal epoxy, or a commercially produced material such as THERMA-GAP™. Heat transfer device 106 provides a thermal interface between device 108 and the second PCB 104. Heat transfer device 106 is typically a mechanically compliant material to allow for minimal applied pressure to the device 108 such that device 108 is not subjected to additional stress through use of heat transfer device 108.

Spacers 141 and fasteners 142 provide for a precision alignment between boards 102 and 104 and the device 108 such that a controlled gap exists in which heat transfer device 106 can properly be accommodated without deleterious air gaps nor excessive pressure applied to device 108. Additionally, the location of the spacers 141 adjacent to the device 108 reduce variations in spacing caused by bow and warpage of board 102 and, to some extent, board 104.

Devices 114-116 that are thermally active but do not require heat transfer device 106 to cool the devices 114-116 are cooled by conduction through first PCB 102, or through convection should air flow be available across first PCB 102.

Device 132 is another heat generating device similar to device 108. However, all devices 108 and 132 that will require additional cooling through heat transfer device 106, second PCB 104, and heatsink 130 are not the same size and/or height. Therefore, each device 108 and 132 must be treated individually using the present invention to best provide heat dissipation for each device 108 and 132. In FIG. 2A, device 132 is shown as having a height 134 smaller than height 136 of device 108. There can be many devices 108 and 132 of varying heights mounted on first PCB 102, all of which can be cooled by the assembly 100 of the present invention, through use of an additional thermal interface 138 and a thermally conductive spacer 140.

Thermal interface 138 provides a thermal path for device 132 that will allow heat generated by device 132 to be dissipated by heatsink 130. Thermal interface 138 can be similar to heat transfer device 106, but can also be a different thermal transfer material to provide a proper thermal dissipative path. As an example thermal interface 138 need not be mechanically compliant so long as thermal interface 106 above it is. Thus, the use of a hardening thermal epoxy may be useful to hold spacer 140 in place during assembly.

Spacer 140 is provided to increase height 134 to approximate height 136. This allows device 108 and device 132 to contact heat transfer device 106, which in turn contacts second PCB 104 and heatsink 130 to transfer heat from devices 108 and 132 to heatsink 130. Spacer 140 is shown as larger in size than device 132, which can provide for heat spreading of the heat generated by device 132 to heatsink 130. Spacer 140 can be of any size relative to device 132. Further, there can be spacers 140 on more than one device 108 and 132.

Where height differences between devices are relatively small and power levels modest these height differences may beneficially be accommodated by selecting varying thicknesses of heat transfer device 106 rather than utilizing thermal interface 138 and spacer 140.

Second PCB 104 is coupled mechanically to first PCB 102 through the use of fasteners 120 and standoffs 122. Fasteners 120 are typically screws, but can be other types of fasteners such as rivets, feedthroughs that are hollow, connectors, or other fasteners. Standoffs 122 are typically unthreaded inserts with a height equal to the height of spacer 141. The fasteners 120 and standoffs 122 are located at mechanically and/or electrically desirable locations on first PCB 102. These locations are typically at the periphery of first PCB 102, but can be anywhere on first PCB 102. Second PCB 104 has areas 124 that are designed to facilitate the transfer of heat from devices 108 and 132, through heat transfer device 106, to a heat sink. Areas 124 comprise plated through holes (PTHs) 126, consisting of holes in board 104 with interior walls of plated copper or other high thermally conductive material. In addition, the region within the hole may be filled with metal, liquid filled areas, or other thermal transfer devices or mechanisms to enhance thermal conduction between material 106 and heatsink 130. Areas 124 can be designed to be the same size, a larger size, or a smaller size than the device 108, depending on the heat dissipation requirements for device 108 and the size of second PCB 104. An additional benefit of PTHs 126 is to provide a means of reducing air pockets in material 106 and to provide a volume where excesses of material 106 may flow in the case of a reduced gap between device 108 and 104.

Thermal interface 128 is coupled to second PCB 104 to equalize and transfer heat from device 108, through heat transfer device 106 and second PCB 104 area 124 to heat sink 130. Although shown as a finned heat sink, heatsink 130 can be any device, e.g., a heat pipe, or a layer on second PCB 104 that acts as an isothermal conduction layer to properly remove the heat generated by device 108. Thermal interface 128 can be electrically conductive, or non-electrically conductive, depending on the design for second PCB 104. For example, if devices 108-116 need to be mounted on second PCB 104, thermal interface 128 can be electrically non-conductive so as not to interfere with signals travelling between devices 108-116 that are mounted on second PCB 104. Thermal interface 128 can be thermal epoxy or any other material which thermally and mechanically bonds board 104 to heatsink 130.

FIG. 2B illustrates the assembly 100 of FIG. 2A as a completed assembly. The thermal coupling of devices 108 and 132, heat transfer device 106, thermal interface 138, spacer 140, second PCB 104 in conjunction with PTHs 126, thermal interface 128, and heatsink 130 provide thermal paths for heat generated by devices 108 and 132 to be dissipated by heatsink 130. Further, airflow can be provided to further cool devices 108 and 132, as well as devices 110-116. Although shown as covering the entire area of second PCB 104, heatsink 130 can be larger or smaller than the area of second PCB 104. Heatsink 130 also acts as a mechanical stabilizer for assembly 100, to provide additional mechanical stability for assemblies 100 that will experience more severe mechanical environments, e.g., vibration.

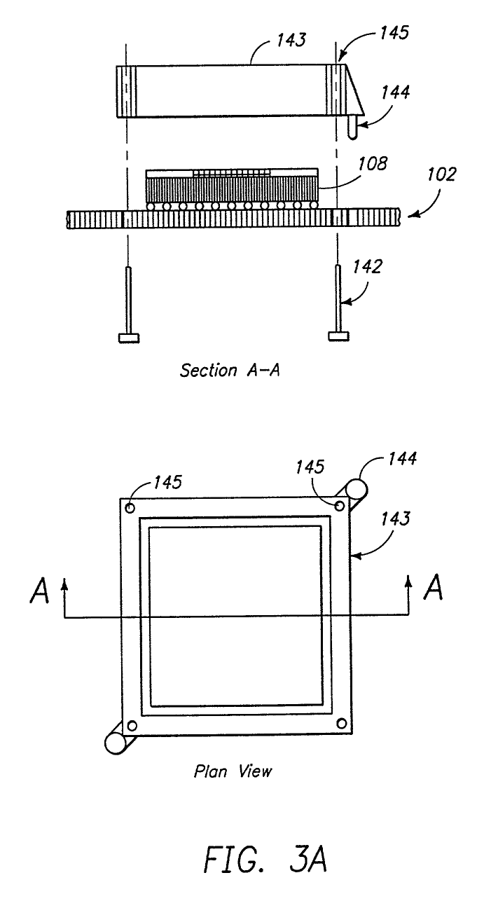

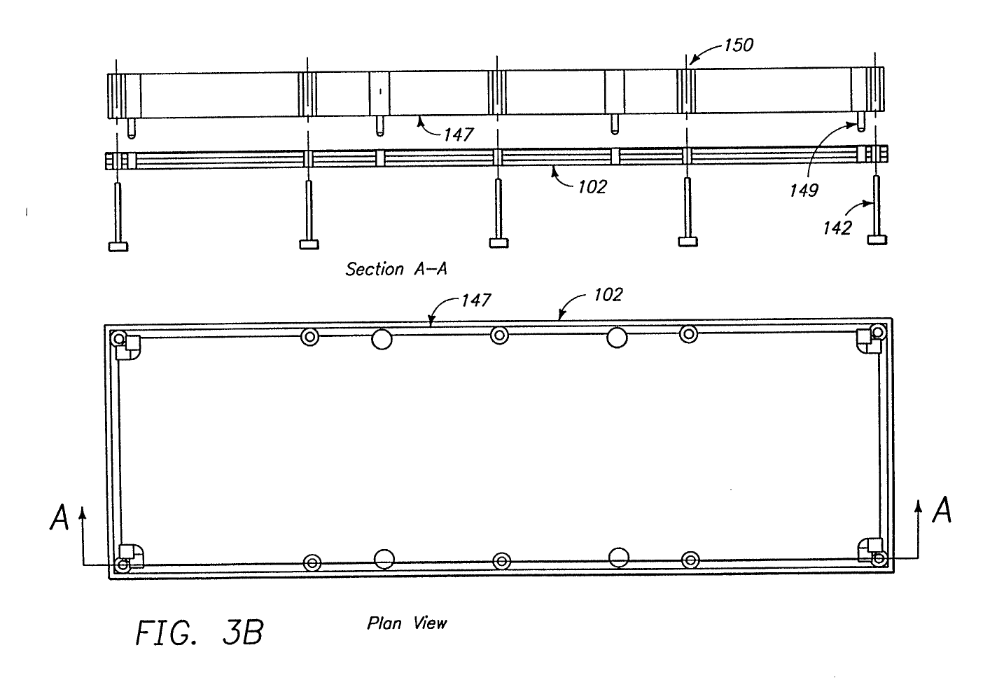

FIG. 3A illustrates in plan and section views a molded plastic spacer 143 that may be used in place of spacers 141 around a device that must be thermally coupled to board 104. This spacer has clearance holes 145 for fasteners 142. Although spacer 143 is shown with four clearance holes 145, spacer 143 can have any number of clearance holes 145 without departing from the scope of the present invention. Imbedded metal spacers may be molded into holes 145 where it may be desirous to provide electrical contact between board 102 and board 104. Spacer 143 substantially surrounds device 108, but can take any shape desired. A feature of the spacer is pins 144 that engage in mating holes of board 102 and act to hold spacer 143 in place until final assembly of assembly 100. An additional benefit of spacer 143 is that it provides complete enclosure of device 108 to prevent accidental damage. Furthermore, spacer 143 may be used to provide thermal isolation between device 108 and the remainder of the board assembly 100.

FIG. 3B illustrates a molded plastic spacer 147 that may be used in place of spacers 141 which have been previously described as used to couple second PCB 104 to first PCB 102. This spacer 147 is shown as having ten clearance holes 150 for fasteners 120, however a larger or smaller number of fasteners may be used as the need and size of the PCBs 102 and 104 require. Imbedded metal spacers may be molded into holes 150 where it may be desirous to provide electrical contact between board 102 and board 104. Furthermore, the entire molded assembly may be formed as a cast metal structure or other metallic form which may be useful in the containment of electromagnetic radiation. A feature of the spacer 147 is pins 149 that engage in mating holes of board 102 and act to hold in place spacer 147 until final assembly of 100. An additional benefit of spacer 147 is that it provides complete enclosure of device 108 to prevent accidental damage. Furthermore, spacer 147 may be used to provide environmental isolation to the internal components of assembly 100.

Embodiments of the Present Invention

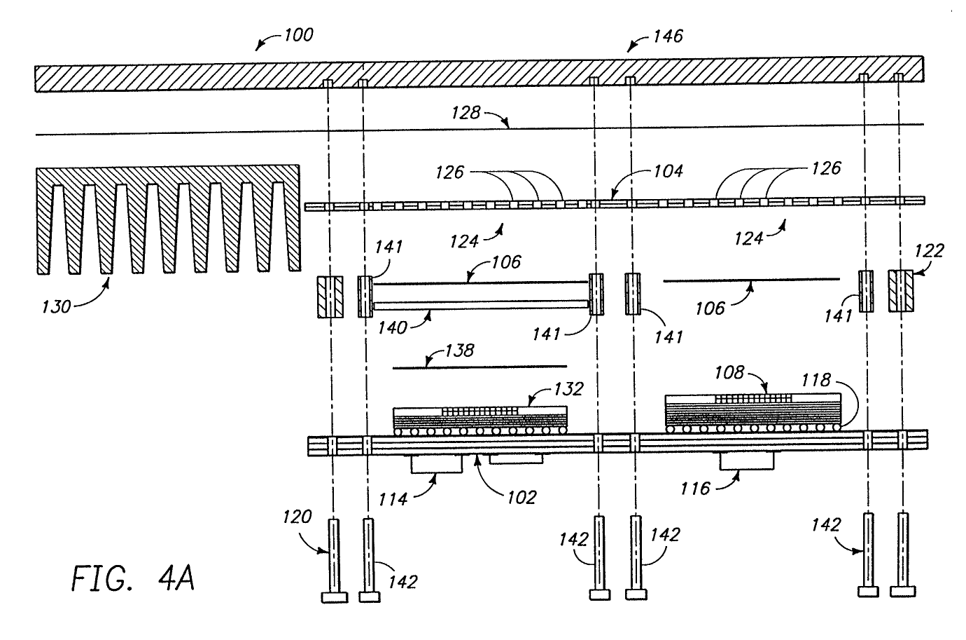

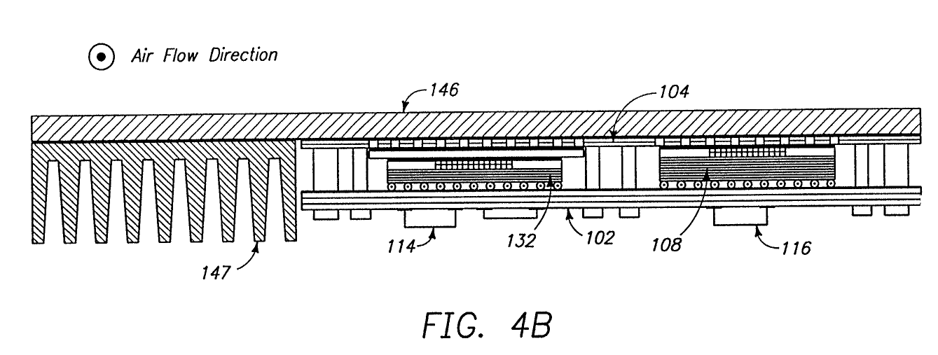

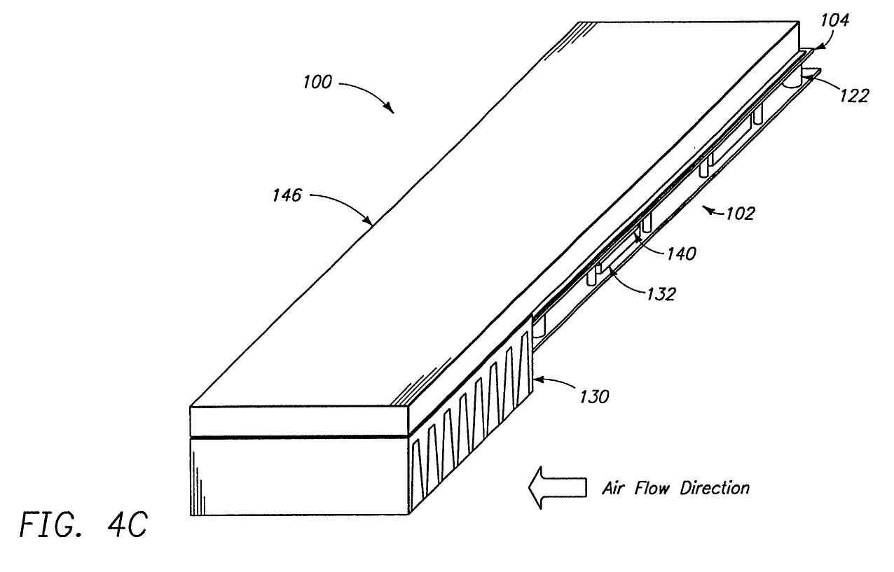

FIGS. 4A-4C illustrate the construction of a printed circuit board using the present invention. FIG. 4A illustrates an exploded view of assembly 100. Assembly 100 comprises first printed circuit board (PCB) 102, second PCB 104, and heat transfer device 106. First PCB 102 can be a single layer PCB or multi-layer PCB, where the multi-layer PCB is comprised of alternating layers of conducting and non-conducting materials to allow electrical signals to be routed from device to device on the first PCB 102. Devices 108, 114, and 116 are shown mounted on first PCB 102. Devices 114 and 116 are shown as being mounted on the opposite side of first PCB 102 as device 108. This illustrates that first PCB 102 can have devices 108, 114, and 116 mounted on both sides.

Device 108 is coupled to first PCB 102 via a Ball Grid Array (BGA) 118. BGA 118 provides electrical contacts between device 108 and first PCB 102. Other methods of electrical coupling between device 108 and first PCB 102 are possible, e.g., wire bonding, solder connections, etc. Further, there can also be thermal coupling between device 108 and PCB 102 if desired.

Heat transfer device 106 couples device 108 to second PCB 104. Heat transfer device 106 is typically a thermally conductive material, e.g., thermal grease, thermal epoxy, or a commercially produced material such as THERMA-GAP™. Heat transfer device 106 provides a thermal interface between device 108 and the second PCB 104. Heat transfer device 106 is typically a mechanically compliant material to allow for minimal applied pressure to the device 108 such that device 108 is not subjected to additional stress through use of heat transfer device 108.

Spacers 141 and fasteners 142 provide for a precision alignment between boards 102 and 104 and the device 108 such that a controlled gap exists in which heat transfer device 106 can properly be accommodated without deleterious air gaps not excessive pressure applied to device 108. Additionally, the location of the spacers 141 adjacent to the device 108 reduce variations in spacing caused by bow and warpage of board 102 and, to some extent, board 104.

Devices 114-116 that are thermally active but do not require heat transfer device 106 to cool the devices 114-116 are cooled by conduction through first PCB 102, or through convection should air flow be available across first PCB 102. Otherwise, additional devices 114-116 can be coupled to second PCB 104 through additional heat transfer devices 106. The present invention is not limited to a single device 108 that is cooled through the use of heat transfer device 106. Any number of devices 108 can be cooled through the use of single or multiple heat transfer devices 106.

Second PCB 104 is coupled mechanically to first PCB 102 through the use of fasteners 120 and standoffs 122. Fasteners 120 are typically screws, but can be other types of fasteners such as rivets, hollow feedthroughs, connectors, or other fasteners. Standoffs 122 are typically unthreaded inserts with a height equal to the height of spacer 141. The fasteners 120 and standoffs 122 are located at mechanically and/or electrically desirable locations on first PCB 102. These locations are typically at the periphery of first PCB 102, but can be anywhere on first PCB 102.

Second PCB 104 has areas 124 that are designed to facilitate the transfer of heat from device 108, through heat transfer device 106, to a heat sink. Areas 124 comprise plated though holes (PTHs) 126, consisting of holes in board 104 with interior walls of plated copper or other high thermally conductive material. In addition, the region within the hole may be filled with metal or other thermal transfer devices or mechanisms to enhance thermal conduction between the material 106 and the heatsink 130. Areas 124 can be designed to be the same size, a larger size, or a smaller size than the device 108, depending on the heat dissipation requirements for device 108 and the size of second PCB 104. An additional benefit of PTHs 126 is to provide a means of reducing air pockets in material 106 and to provide a volume where excesses of material 106 may flow in the case of a reduced gap between device 108 and board 104. Still another benefit of PTHs 126 can be to adjust the thermal conductivity of the paths of devices 108 and 132 to the common “isothermal” lateral heat spreader block 146 such that if the two devices have differing heat flow then the conductivity in each path can be adjusted such that the junction temperature of each device will be the same. This can be beneficial in improving timing margins of digital devices.

Thermal interface 128 is coupled to second PCB 104 to equalize and transfer heat from device 108, through heat transfer device 106 and second PCB 104 area 124 to lateral heat spreader block 146. Heat spreader block 146 is desirably of a thermally high conductivity material such as aluminum which allows the heat emanating from devices 108 and 132 to flow to heat sink 130 which is located outside of the volume used by boards 102 and 104. Additionally, heat spreader block 146 may incorporate imbedded heat pipes to enhance lateral thermal conduction and/or reduce height. Although shown as a finned heat sink, heatsink 130 can be any device, e.g., a heat pipe, that can conduct heat out of the heat spreader block 146. Thermal interface 128 can be electrically conductive, or non-electrically conductive, depending on the design for second PCB 104. For example, if devices 108-116 need to be mounted on second PCB 104, thermal interface 128 should be electrically non-conductive so as not to interfere with signals travelling between devices 108-116 that are mounted on second PCB 104. Thermal interface 128 can be thermal epoxy or any other material which thermally and mechanically bonds board 104 to heatsink 130 and between heatsink 130 and heat spreader block 146.

As opposed to FIG. 1A, heatsink 130 is now shown as being mounted outboard the volume occupied by PCB 102 and second PCB 104. This flexibility of the present invention to mount the heatsink 130 at multiple locations provides additional design capabilities, i.e., the height of assembly 100 is now independent of the height of heatsink 130. Thus, heat dissipative capability is provided without additional volume requirements for assembly 100 other than the height of heat spreader block 146.

FIG. 4B illustrates the assembly 100 as a completed assembly. The thermal coupling of device 108, heat transfer device 106, second PCB 104, thermal interface 128, heat spreader block 146 and heatsink 130 provide a thermal path for heat generated by device 108 to be dissipated by heatsink 130. Further, airflow can be provided to further cool device 108 and devices 114-116. Heatsink 130 can be larger or smaller than the height of PCB 102, PCB 104 and heat spreader block 146. Heat spreader block 146 also acts as a mechanical stabilizer for assembly 100, to provide additional mechanical stability for assemblies 100 that will experience more severe mechanical environments, e.g., vibration.

FIG. 4C illustrates assembly 100 in an isometric view. Heatsink 130 is shown as residing outboard of first PCB 102 and second PCB 104. Thermal interface 128 is shown on the opposite side of second PCB 104, and is shown as smaller than second PCB 104 to illustrate the flexibility of the design of the present invention. Airflow can again be provided to increase the heat dissipation capabilities of assembly 100.

The design of FIGS. 4A-4C can be used where assembly 100 height is at a premium, or, where the heatsink 130 would be more efficient located outboard first PCB 102 and second PCB 104 than it would be if heatsink 130 sat atop second PCB 104. This might occur when it is desirous to locate assembly 100 adjacent to similar assemblies 100 as close as practical to minimize electrical interconnect lengths, where airflow over the top of second PCB 104 is less than airflow outboard of assembly 100. Further, the placement of heatsink 130 outboard first PCB 102 and second PCB 104 allows heatsink 130 to be electrically grounded, or placed at a desired potential, using both first PCB 102 and second PCB 104.

Thermal Considerations

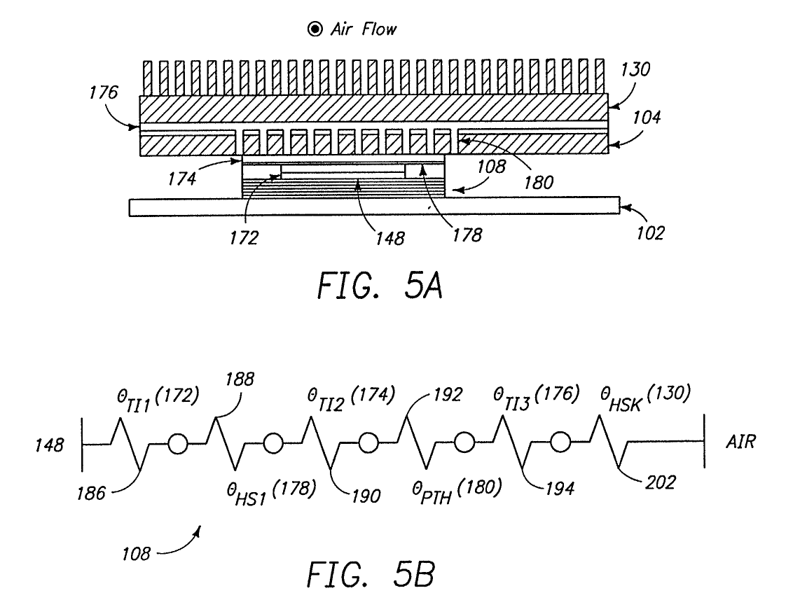

FIGS. 5A and 5B illustrate the thermal considerations of a printed circuit board embodying the present invention.

FIG. 5A illustrates assembly 100 with the various thermal interfaces described for the present invention. The silicon die is represented as die 148. Thermal Interface 1 (TI1) 172 is the thermal interface internal to the device 108 between device heatspreader 178 and silicon die 148. Heatspreader 178 may not always be present in which case thermal interface 172 would be used to represent the thermal resistance of the outside package surface to the silicon die 148, e.g. molding compound. Thermal Interface 2 (TI2) 174 is the interface between second PCB 104 and device 108. Thermal Interface 3 (TI3) 176 is the interface between second PCB 104 and heatsink 130.

Plated through holes (PTH) 180 is the area 124 of PCB 104 that allows thermal conduction through the board 104. Heatsink (HSK) 130 is the device that couples the heat flow to the air or in some cases to thermal pipes to remote radiators. FIG. 5B illustrates the thermal schematic for the assembly 100 shown in FIG. 5A. Starting from die 148, TI1 172 receives a thermal resistance value, theta TI1 (θ_{TI1}) 186, HS1 178 receives a thermal resistance value theta HS1 (θ_{HS1}) 188, TI2 174 receives a thermal resistance value, theta TI2 (θ_{TI2}) 190, HV 180 receives a thermal resistance value, theta HV (θ_{HV}) 192, TI3 176 receives a thermal resistance value, theta TI3 (θ_{TI3}) 194, and HSK 130 receives a thermal resistance value, theta HSK (θ_{HSK}) 202. The thermal resistances of the assembly 100 are determined in terms of degrees centigrade per watt (° C./W). To determine the total temperature rise across the interface from silicon die 148 to ambient air, the total power of the device is multiplied by the total thermal resistance:

$$Δ T = {\sum }_{i = 1}^{n} θ i * W$$

For example, a 1 ° C./W total thermal resistance for a 50-Watt device would yield a total temperature change of 50° C.

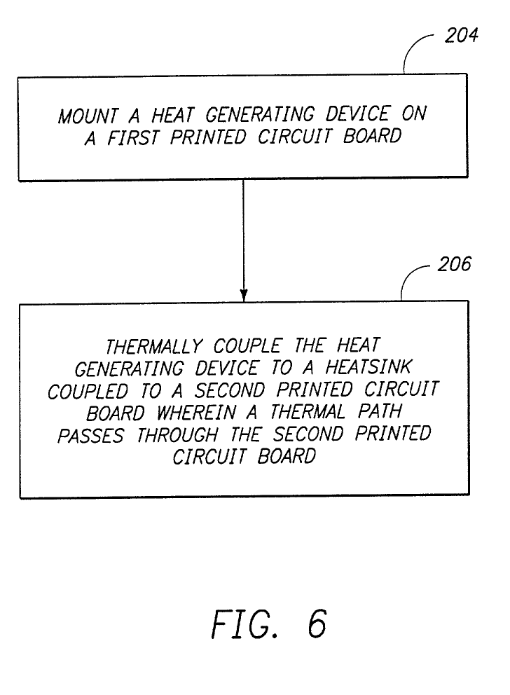

FIG. 6 illustrates a flow chart describing the steps used in practicing the present invention.

Block 204 represents the step of mounting a heat generating device on a first printed circuit board.

Block 206 represents the step of thermally coupling the heat generating device to a heatsink coupled to a second printed circuit board, wherein a thermal path passes through the second printed circuit board.

Further Heat Sink and PCB Embodiments

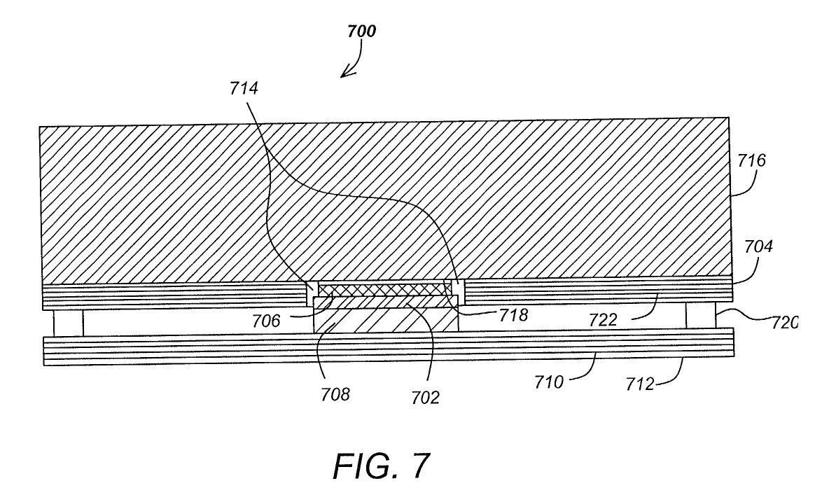

FIG. 7 is a diagram illustrating an embodiment of the present invention. In this embodiment, the modular circuit board assembly 700 comprises a substrate 702, a circuit board 704, and a component 706 such as an integrated circuit or other heat-dissipating component, disposed between the circuit board 704 and the substrate 702. The component 706 is physically and electrically coupled to the substrate 702. The substrate 702 may be physically and electrically coupled to a socket 708, thereby providing a path for signals between one or more of the layers 710 of a motherboard 712 and the component 706.

In one embodiment, an aperture 714 is disposed at least partially through the circuit board 704. At least a portion of the component 706 extends to within the aperture 714 and thermally communicates with a heat dissipation device such as a heat sink. In one embodiment, a thermal interface material 718 such as a thermal grease, is interposed between the top surface of the component 706 and the bottom surface of the heat sink. Standoffs 720 are disposed between the motherboard 712 and the circuit board 704. In one embodiment, the circuit board 704 includes a one or more passive and/or active components assembled together to form a power conditioning or voltage regulation module (VRM). Power can be supplied to one or more of conductive surfaces in the layers 722 of the circuit board 704 from the motherboard 712 using the coaxial power standoffs described in the related applications referenced in the beginning of this disclosure. In one embodiment, the circuit board and the substrates of the modular assembly 700 are impermanently coupled together. That is, the modular assembly 700 can be assembled without permanent press-fit or solder connections, and can be therefore disassembled if desired.

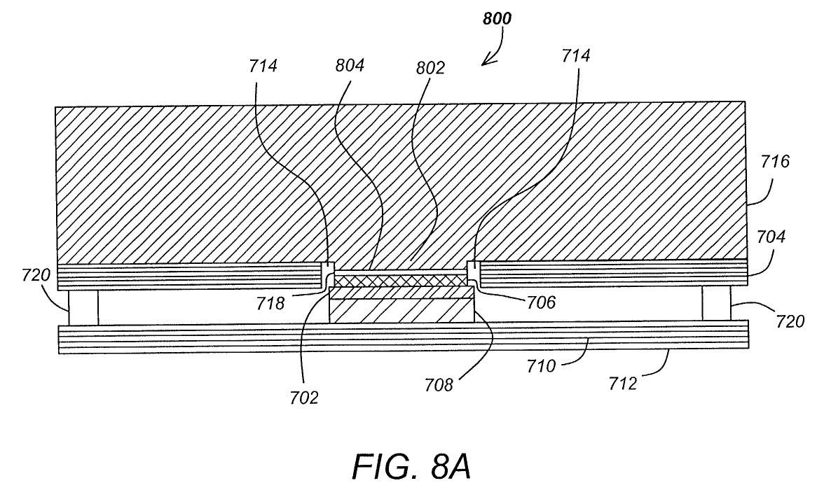

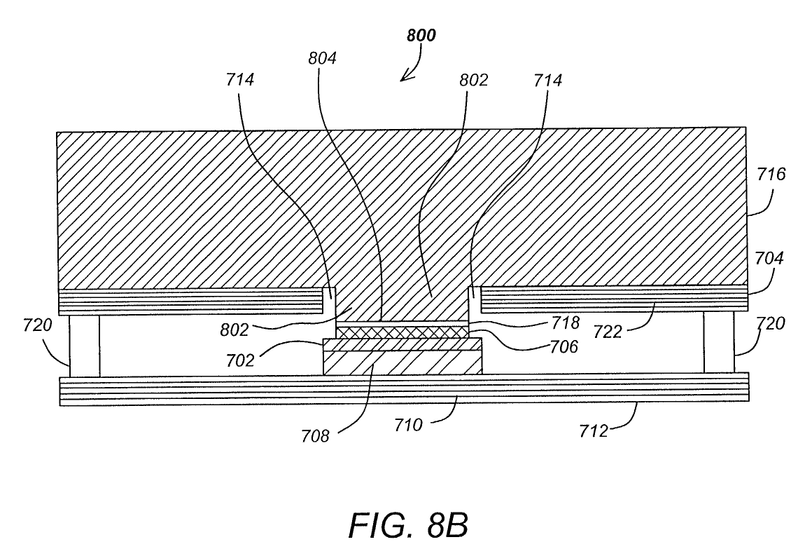

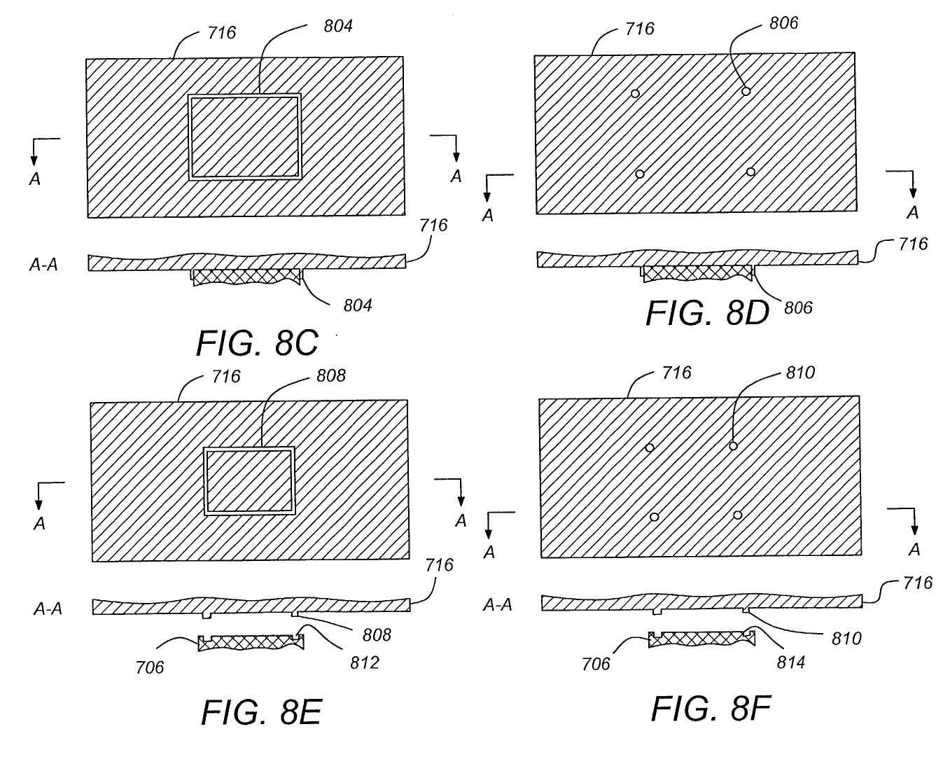

FIG. 8A is a diagram illustrating another embodiment of the present invention. In this embodiment, the heat dissipating device or heat sink 716 or the modular circuit board assembly 800 includes a mesa 802. The mesa 802 extends to within the aperture 714, where it provides thermal connectivity with the component 706. As with the embodiment illustrated in FIG. 7, a thermal interface material 718 can be disposed between the mesa 802 and the component 706.

FIG. 8B is a diagram illustrating another embodiment of the present invention. In this embodiment, the mesa 802 extends all the way through the aperture 714 to the side of the circuit board 704 opposing the heat sink 716.

In addition to the mesa 802 disclosed above, the heat sink 716 may also comprise a depressed portion, sized and shaped to accept the component 706 or a member thermally attached to the component 706. The depressed portion can include the location and/or retention features discussed below.

FIGS. 8C and 8D are diagrams depicting further embodiments of the present invention. In these embodiments, heat sink 716 includes features 804 and 806 that can be used as location and/or retention features. As shown in FIG. 8C, first feature 804 includes an elevated portion that is shaped and sized so as to accept the periphery of the component 706 therebetween, thus providing location and/or retention for the component 706 and/or related devices relative to the heat sink 716 and the components affixed thereto. As shown in FIG. 8D, a second feature 806 can be used such that the surfaces of the second features 806 contact one or more outer surfaces of the component.

FIGS. 8E and 8F are diagrams depicting another embodiment of the present invention in which the features 808, 810 interface with matching features 812, 814 disposed on an external surface of the component 706 or a member physically or thermally coupled to the component 706. While the illustrations presented in FIGS. 8E and 8F show the heat sink 716 with male features 808, 810 and the component 706 with female features 812, 814, this need not be the case . . . male features may instead be disposed on the component 706. Further, the scope of the applicants' invention includes other location and/or retention features that may be utilized.

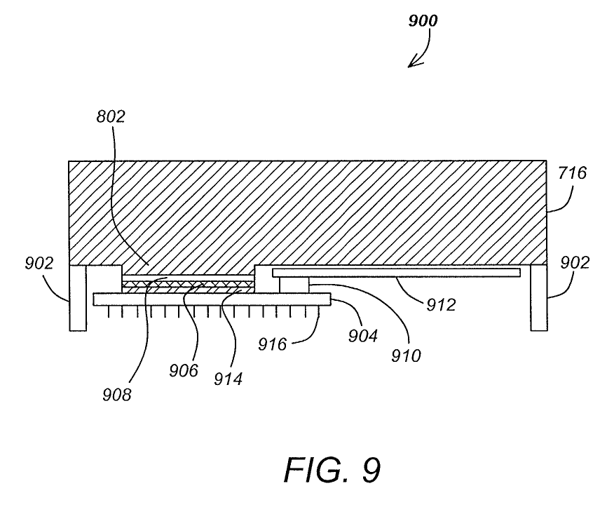

FIG. 9 is a diagram illustrating another embodiment of the present invention. In this embodiment, a modular circuit board assembly 900 includes a component 906 die mounted on and in electrical communication with a substrate 914. The substrate 914 is mounted on an interposer circuit board 904, which makes electrical contact with a motherboard (not shown), thus providing an electrical path for communication between the motherboard and the die. A thermal interface material 908 may be placed on an upper surface of the component 906 die to provide for improved thermal communication between the component 906 die and the heat sink mesa 802. In one embodiment, an external surface of the heat sink mesa 802 includes location and/or retention features, as described above. The heat sink 716 is mounted to a frame 902, which supports the structure of the modular circuit board assembly 900. A second circuit board 912 (such as a voltage regulation module, or VRM) adjacent the component 906 die is communicatively coupled to the interposer circuit board 904. In one embodiment, this is accomplished by the use of coaxial conductors 910 described fully in the cross-referenced patent applications.

The second circuit board 912 can be thermally coupled to the heat sink 716 by direct content, or contact thorough a thermal interface material. The heat sink 716 may also comprise a second mesa, for making thermal contact with the second circuit board 912. If desired, elements on the second circuit board 912 and/or the second mesa external surface can include location and/or retention features.

In one embodiment, the second circuit board 912 is disposed adjacent to the component 906 die, thus minimizing size and conserving space in the z (vertical) axis. If desired, the top surface of the second circuit board 912 can be disposed substantially co-planar with that of the top surface of the component 906 die, or thermal transfer element thermally coupled to the die. In another embodiment, the “height” of the mesa 802 is selected to account for any differences in the height of the component 906 die and related assemblies, and the second circuit board 912.

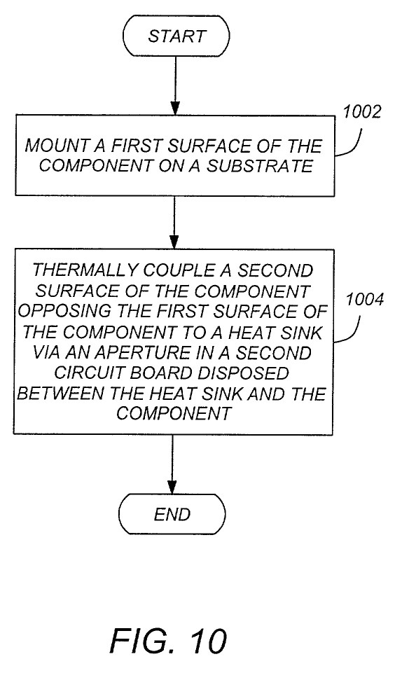

FIG. 10 is a flow chart illustrating exemplary method steps used to practice one embodiment of the present invention. A first surface of a component 706 is mounted on a substrate 702, as shown in block 1002. A second surface of the component 706 which opposes the first surface of the component 706 is then thermally coupled to a heat sink 716 via an aperture 714 in a second circuit board 704 disposed between the heat sink 716 and the component 706, as shown in block 1004.

Conclusion

This concludes the description of the preferred embodiment of the invention. The following describes some alternative embodiments for accomplishing the present invention. Assembly 100 can have both rigid and flexible layers to accommodate the needs of PCB designers without departing from the scope of the present invention. Further, the thicknesses of assembly 100 can be modified to accommodate components as needed.

Although described with respect to thermal considerations, the present invention can also be used to shield device 108 from outside radiative effects, e.g., radiation, electromagnetic interference, etc. Further, device 108 can be shielded from emitting radiation and/or electromagnetic signals to the outside world through the use of the present invention. The present invention can also be used to provide power to devices through the second PCB 104 by contacting the device 108 through spacers 124 or standoffs 122.

In summary, the present invention discloses an encapuslated circuit assembly and a method for making such an assembly. The assembly comprises a first printed circuit board, a second printed circuit board, and a heat transfer device. The second printed circuit board comprises a heatsink, and the heat transfer device couples between a device mounted on the first printed circuit board and the second printed circuit board for transferring heat from the device to the heatsink of the second printed circuit board.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A modular circuit board assembly, comprising:
a substrate;
a circuit board; and
a component, disposed between the circuit board and the substrate, the component physically and electrically coupled to the substrate.

2. The modular circuit board assembly of claim 1, wherein the circuit board comprises an aperture disposed therethrough.

3. The modular circuit board assembly of claim 2, wherein the aperture is sized to accept a heat sink mesa therethrough.

4. The modular circuit board assembly of claim 3, wherein the mesa includes an external surface having at least one first location feature, the mesa location feature cooperatively interactable with at least one second location feature.

5. The modular circuit board assembly of claim 4, wherein the second location feature is disposed on an external surface of the component.

6. The modular circuit board assembly of claim 5, wherein the second location feature is disposed on an external surface of a member physically coupled to the component.

7. The modular circuit board assembly of claim 4, wherein the location feature is further a retention feature.

8. The modular circuit board assembly of claim 2, wherein the mesa includes an external surface having at least one first retention feature, the mesa retention feature cooperatively interactable with at least one second retention feature.

9. The modular circuit board assembly of claim 1, wherein the component is electrically coupled to the substrate via a ball grid array.

10. The modular circuit board assembly of claim 1, wherein a power signal is provided to the circuit board via a path distinct from the substrate.

11. The modular circuit board assembly of claim 1, further comprising a socket, physically coupled between the substrate and the motherboard, the socket electrically coupling the substrate and the motherboard.

12. The modular circuit board assembly of claim 1, wherein the component is mounted on a first side of the substrate, the first side of the substrate facing the circuit board.

13. The modular circuit board assembly of claim 1, wherein the first circuit board and the substrate are impermanently coupled.

14. A modular circuit board assembly, comprising:
a substrate, having a component mounted thereon, the component including a first surface; and
a circuit board, disposed adjacent the component, the circuit board having a first surface substantially co-planar with the component first surface.

15. The modular circuit board assembly of claim 14, further comprising a heat dissipation device having a substantially planar surface in thermal contact with the circuit board first surface and the component first surface.

16. A heat sink, comprising:
an external surface; and
a mesa extending from the external surface, the mesa sized to be insertable through a circuit board aperture to thermally communicate with a heat dissipating component disposed on a side of the circuit board opposing the heat sink.

17. The heat sink of claim 16, wherein the mesa further comprises at least one mesa location feature, the mesa location feature cooperatively interactable with at least one second location feature.

18. The heat sink of claim 16, wherein the second location feature is disposed on an external surface of the heat dissipating component.

19. The heat sink of claim 16, wherein the mesa location feature is further a retention feature.

20. The heat sink of claim 16, wherein the mesa further comprises at least one mesa retention feature cooperatively interactable with at least one second retention feature.

21. The heat sink of claim 20, wherein the second retention feature is disposed on an external surface of the heat dissipating component.

22. A heat sink, comprising:
an external surface; and
a depression sized to accept a component insertable through a circuit board aperture to thermally communicate with a heat dissipating component disposed on a side of the circuit board opposing the heat sink.

23. An article of manufacture, formed by performing the steps of:
mounting a first surface of the component on a substrate; and
thermally coupling a second surface of the component opposing the first surface of the component to a heat sink via an aperture in a second circuit board disposed between the heat sink and the component.

24. The article of manufacture of claim 23, wherein the second surface of the component is thermally coupled to a mesa portion of the heat sink.

25. The article of manufacture of claim 24, wherein the mesa portion includes location features.

26. The article of manufacture of claim 24, wherein the mesa portion includes retention features.
